(19) United States
(12) Patent Application Publication
(10) Pub. No.: US 2021/0193953 A1
(43) Pub. Date: Jun. 24, 2021

(54) ORGANIC LIGHT EMITTING DIODE DISPLAY SUBSTRATE, ORGANIC LIGHT EMITTING DIODE DISPLAY APPARATUS, AND METHOD OF FABRICATING ORGANIC LIGHT EMITTING DIODE DISPLAY SUBSTRATE

(71) Applicant: BOE Technology Group Co., Ltd., Beijing (CN)

(72) Inventors: Fengjuan Liu, Beijing (CN); Zhen Song, Beijing (CN)

(73) Assignee: BOE Technology Group Co., Ltd., Beijing (CN)

(21) Appl. No.: 16/080,973

(22) PCT Filed: Sep. 26, 2017
(86) PCT No.: PCT/CN2017/103387

§ 371 Date: Aug. 29, 2018

(51) Int. Cl. H01L 51/52; H01L 27/32; H01L 51/56

(52) U.S. Cl. CPC H01L 51/5228; H01L 27/322; H01L 27/3244; H01L 2227/323; H01L 51/5284; H01L 51/56; H01L 51/5234

(57) ABSTRACT

The present application discloses an organic light emitting diode display substrate having a subpixel region and an inter-subpixel region. The organic light emitting diode display substrate includes a base substrate and an auxiliary cathode on the base substrate. The auxiliary cathode includes a transparent conductive sub-layer and a metallic conductive sub-layer on a side of the transparent conductive sub-layer distal to the base substrate. The metallic conductive sub-layer is substantially in the inter-subpixel region.

### TECHNICAL FIELD

The present invention relates to display technology, more particularly, to an organic light emitting diode display substrate, an organic light emitting diode display apparatus, and a method of fabricating an organic light emitting diode display substrate.

### BACKGROUND

Organic light emitting diode (OLED) display apparatuses are self-emissive devices, and do not require backlights. OLED display apparatuses also provide more vivid colors and a larger color gamut as compared to the conventional liquid crystal display (LCD) apparatuses. Further, OLED display apparatuses can be made more flexible, thinner, and lighter than a typical LCD. An OLED display apparatus typically includes an anode, an organic layer including a light emitting layer, and a cathode. OLEDs can either be a bottom-emission type OLED or a top-emission type OLED. In bottom-emission type OLEDs, the light is extracted from an anode side. In bottom-emission type OLEDs, the anode is generally transparent, while a cathode is generally reflective. In a top-emission type OLED, light is extracted from a cathode side. In a top-emission type OLED, the cathode is optically transparent, while the anode is reflective.

### SUMMARY

In one aspect, the present invention provides an organic light emitting diode display substrate having a subpixel region and an inter-subpixel region, comprising a base substrate; and an auxiliary cathode on the base substrate; wherein the auxiliary cathode comprises a transparent conductive sub-layer and a metallic conductive sub-layer on a side of the transparent conductive sub-layer distal to the base substrate; and the metallic conductive sub-layer is substantially in the inter-subpixel region.

Optionally, the metallic conductive sub-layer is in contact with the transparent conductive sub-layer.

Optionally, the organic light emitting diode display substrate further comprises a black matrix layer on the base substrate; wherein the auxiliary cathode is on a side of the black matrix layer distal to the base substrate; and a projection of the black matrix layer on the base substrate substantially covers a projection of the metallic conductive sub-layer on the base substrate.

Optionally, the transparent conductive sub-layer is in the subpixel region and the inter-subpixel region.

Optionally, the organic light emitting diode display substrate further comprises an overcoat layer on the base substrate; wherein the auxiliary cathode is on a side of the overcoat layer distal to the base substrate.

Optionally, the metallic conductive sub-layer is in contact with the transparent conductive sub-layer; and the transparent conductive sub-layer is in contact with the overcoat layer.

Optionally, the transparent conductive sub-layer comprises a metal oxide.

Optionally, the organic light emitting diode display substrate is a color filter substrate comprising a color filter.

Optionally, a projection of the transparent conductive sub-layer on the base substrate substantially covers a projection of the color filter on the base substrate.

In another aspect, the present invention provides an organic light emitting diode display apparatus, comprising an array substrate having a plurality of organic light emitting diodes; and any one of above organic light emitting diode display substrates facing the array substrate; wherein the array substrate comprises a cathode for the plurality of organic light emitting diodes; and the cathode is electrically connected to the auxiliary cathode in the organic light emitting diode display substrate.

In another aspect, the present invention provides a method of fabricating an organic light emitting diode display substrate having a subpixel region and an inter-subpixel region, comprising forming an auxiliary cathode on a base substrate; wherein forming the auxiliary cathode comprises forming a transparent conductive sub-layer and forming a metallic conductive sub-layer on a side of the transparent conductive sub-layer distal to the base substrate; and the metallic conductive sub-layer is formed substantially in the inter-subpixel region.

Optionally, forming the transparent conductive sub-layer comprises depositing a transparent conductive material on the base substrate in a room temperature deposition process.

Optionally, the metallic conductive sub-layer is formed to be in contact with the transparent conductive sub-layer.

Optionally, the method further comprises forming a black matrix layer on the base substrate; wherein forming the auxiliary cathode comprises forming the auxiliary cathode on a side of the black matrix layer distal to the base substrate; and the metallic conductive sub-layer is formed so that a projection of the black matrix layer on the base substrate substantially covers a projection of the metallic conductive sub-layer on the base substrate.

Optionally, the transparent conductive sub-layer is formed in the subpixel region and the inter-subpixel region.

Optionally, the method further comprises forming an overcoat layer on the base substrate; wherein forming the auxiliary cathode comprises forming the auxiliary cathode on a side of the overcoat layer distal to the base substrate.

Optionally, the metallic conductive sub-layer is formed to be in contact with the transparent conductive sub-layer, and the transparent conductive sub-layer is formed to be in contact with the overcoat layer.

Optionally, the transparent conductive sub-layer is made of a metal oxide.

Optionally, the method further comprises forming a color filter.

Optionally, the transparent conductive sub-layer is formed so that a projection of the transparent conductive sub-layer on the base substrate substantially covers a projection of the color filter on the base substrate.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of an organic light emitting diode display substrate in some embodiments according to the present disclosure.

FIG. 2 is a schematic diagram illustrating the structure of an organic light emitting diode display substrate in some embodiments according to the present disclosure.

FIG. 3 is a schematic diagram illustrating the structure of an organic light emitting diode display substrate in some embodiments according to the present disclosure.

FIG. 4 is a schematic diagram illustrating the structure of an organic light emitting diode display substrate in some embodiments according to the present disclosure.

FIG. 5 is a schematic diagram illustrating the structure of an organic light emitting diode display apparatus in some embodiments according to the present disclosure.

FIGS. 6A to 6E illustrate a process of fabricating an organic light emitting diode display substrate in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

In conventional organic light emitting diode display apparatus, especially a conventional top emission type organic light emitting diode display apparatus the cathode for the organic light emitting diodes is typically made of a transparent conductive material such as indium zinc oxide or transparent metals such as magnesium-silver, to ensure light transmission of the light produced by the organic light emission layer. These transparent conductive materials typically have relatively high specific resistance, which presents a serious issue especially for a large size display panel. To lower the resistance of the cathode in the conventional organic light emitting diode display apparatus, sometimes an auxiliary cathode is used.

In some embodiments, an auxiliary cathode can be made on the counter substrate facing the array substrate of the organic light emitting diode display apparatus. In one example, the auxiliary cathode is made of a non-transparent metallic material, and can be made in the black matrix area. In doing so, the auxiliary cathode can be made of a relatively low specific resistance, and at the same time does not affect light transmission in the display apparatus. The auxiliary cathode in the counter substrate is electrically connected to the cathode in the array substrate.

The auxiliary cathode may be deposited on any of various layers in the counter substrate. In one example, the auxiliary cathode is formed on an overcoat layer of the counter substrate. Optionally, the auxiliary cathode is formed on a black matrix of the counter substrate. These layers of the counter substrate are made of organic materials, which do not provide good adhesion with the metallic auxiliary cathode. Portions of the metal lines of the auxiliary cathode deposited on the counter substrate (e.g., on the overcoat layer of the counter substrate) sometimes become loose or fall off the counter substrate. The problem becomes particularly severe when the metal lines are made of a small width to enhance aperture ratio of the display apparatus.

Accordingly, the present disclosure provides, inter alia, an organic light emitting diode display substrate, an organic light emitting diode display apparatus, and a method of fabricating an organic light emitting diode display substrate that substantially obviate one or more of the problems due to limitations and disadvantages of the related art. In one aspect, the present invention provides an organic light emitting diode display substrate having a subpixel region and an inter-subpixel region. In some embodiments, the organic light emitting diode display substrate includes a base substrate and an auxiliary cathode on the base substrate. The auxiliary cathode includes a transparent conductive sub-layer and a metallic conductive sub-layer on a side of the transparent conductive sub-layer distal to the base substrate. The metallic conductive sub-layer is substantially in the inter-subpixel region.

As used herein, a subpixel region refers to a light emission region of a subpixel, such as a region corresponding to a pixel electrode in a liquid crystal display or a region corresponding to a light emissive layer in an organic light emitting diode display panel. Optionally, a pixel may include a number of separate light emission regions corresponding to a number of subpixels in the pixel. Optionally, the subpixel region is a light emission region of a red color subpixel. Optionally, the subpixel region is a light emission region of a green color subpixel. Optionally, the subpixel region is a light emission region of a blue color subpixel. Optionally, the subpixel region is a light emission region of a white color subpixel. As used herein, an inter-subpixel region refers to a region between adjacent subpixel regions, such as a region corresponding to a black matrix in a liquid crystal display or a region corresponding a pixel definition layer in an organic light emitting diode display panel. Optionally, the inter-subpixel region is a region between adjacent subpixel regions in a same pixel. Optionally, the inter-subpixel region is a region between two adjacent subpixel regions from two adjacent pixels. Optionally, the inter-subpixel region is a region between a subpixel region of a red color subpixel and a subpixel region of an adjacent green color subpixel. Optionally, the inter-subpixel region is a region between a subpixel region of a red color subpixel and a subpixel region of an adjacent blue color subpixel. Optionally, the inter-subpixel region is a region between a subpixel region of a green color subpixel and a subpixel region of an adjacent blue color subpixel.

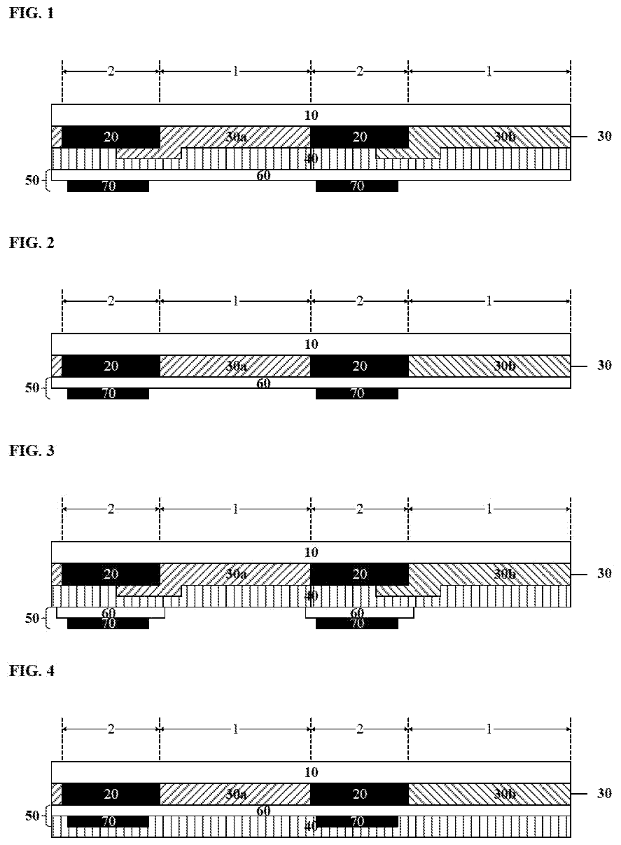

FIG. 1 is a schematic diagram illustrating the structure of an organic light emitting diode display substrate in some embodiments according to the present disclosure. Referring to FIG. 1, the organic light emitting diode display substrate in some embodiments has a subpixel region 1 and an inter-subpixel region 2. The organic light emitting diode display substrate includes a base substrate 10 and an auxiliary cathode 50 on the base substrate 10. The auxiliary cathode 50 includes a transparent conductive sub-layer 60 and a metallic conductive sub-layer 70 on a side of the transparent conductive sub-layer 60 distal to the base substrate 10. The metallic conductive sub-layer 70 is substantially in the inter-subpixel region 2.

By first forming a transparent conductive sub-layer 60 on the display substrate, followed by forming the metallic conductive sub-layer 70 on the transparent conductive sub-layer 60, the properties and performance of the auxiliary cathode are significantly enhanced. The transparent conductive sub-layer 60 has a relatively high adhesion with the organic material layers (e.g., the overcoat layer, the black matrix layer, or the color filter). At the same time, the metallic conductive sub-layer 70 also has a relatively high adhesion with the transparent conductive sub-layer 60. By making the auxiliary cathode 50 to have the metallic conductive sub-layer 70 stacked on the transparent conductive sub-layer 60, the overall resistance of the auxiliary cathode is further reduced, and the issue of metal fall-off the display substrate is obviated.

In some embodiments, the transparent conductive sub-layer 60 is made of a metal oxide material. Examples of metal oxides for making the transparent conductive sub-layer 60 include, but are not limited to, indium tin oxide, indium zinc oxide, and so on.

In some embodiments, the metallic conductive sub-layer 70 is made of a metal or an alloy. Examples of metals or alloys suitable for making the metallic conductive sub-layer 70 include, but are not limited to, copper, aluminum, silver, gold, titanium, tungsten, nickel, and so on.

As discussed above, the metallic conductive sub-layer 70 has a relatively high adhesion with the transparent conductive sub-layer 60. In some embodiments, the metallic conductive sub-layer 70 is in contact with the transparent conductive sub-layer 60.

Referring to FIG. 1, the organic light emitting diode display substrate in some embodiments further includes a black matrix layer 20 on the base substrate 10. Optionally, the black matrix layer 20 is in the inter-subpixel region 2 and defines the subpixel region 1. Optionally, the auxiliary cathode 50 is on a side of the black matrix layer 20 distal to the base substrate 10. For example, the transparent conductive sub-layer 60 is on a side of the black matrix layer 20 distal to the base substrate 10, and the metallic conductive sub-layer 70 is on a side of the transparent conductive sub-layer 60 distal to the black matrix layer 20. Optionally, a projection of the black matrix layer 20 on the base substrate 10 substantially covers a projection of the metallic conductive sub-layer 70 on the base substrate 10. Optionally, the projection of the black matrix layer 20 on the base substrate 10 substantially overlaps with the projection of the metallic conductive sub-layer 70 on the base substrate 10.

Because the transparent conductive sub-layer 60 is made of a transparent material, it may be disposed in a region not limited to that of the black matrix layer 20. In one example, the transparent conductive sub-layer 60 may be disposed in both the subpixel region 1 and the inter-subpixel region 2. Optionally, the transparent conductive sub-layer 60 may be formed as a layer substantially throughout the counter substrate, e.g., without patterning. By having a large area transparent conductive sub-layer 60, the resistance of the auxiliary cathode 50 can be further decreased.

In some embodiments, the organic light emitting diode display substrate further includes an overcoat layer 40 on the base substrate 10 to planarize the surface of the display substrate. The auxiliary cathode 50 is on a side of the overcoat layer 40 distal to the base substrate 10. For example, the transparent conductive sub-layer 60 is on a side of the overcoat layer 40 distal to the base substrate 10, and the metallic conductive sub-layer 70 is on a side of the transparent conductive sub-layer 60 distal to the base substrate 10.

As discussed above, the transparent conductive sub-layer 60 has a relatively high adhesion both with a metallic material and with an organic material. Accordingly, the transparent conductive sub-layer 60 is between the metallic conductive sub-layer 70 and the overcoat layer 40. Moreover, the transparent conductive sub-layer 60 is in contact with the metallic conductive sub-layer 70 on a first side, and in contact with the overcoat layer 40 on a second side opposite to the first side.

In some embodiments, the organic light emitting diode display substrate further includes a color filter 30. The color filter 30 may include a plurality of color filter blocks (e.g., the color filter blocks 30a and 30b in FIG. 1). Optionally, the color filter 30 is at least partially in the subpixel region 1. Optionally, a projection of the transparent conductive sub-layer 60 on the base substrate 10 substantially covers a projection of the color filter 30 on the base substrate 10.

Various alternative implementations may be practiced according to the present disclosure. For example, the auxiliary cathode 50 may be disposed on a layer other than the overcoat layer 40. FIG. 2 is a schematic diagram illustrating the structure of an organic light emitting diode display substrate in some embodiments according to the present disclosure. Referring to FIG. 2, the organic light emitting diode display substrate includes a black matrix layer 20 and a color filter 30 on the base substrate 10. The auxiliary cathode 50 is disposed directly on the black matrix layer 20 and the color filter 30 (e.g., the overcoat layer is absent in the organic light emitting diode display substrate of FIG. 2). The black matrix layer 20 and the color filter 30 are made of organic materials. By having a transparent conductive sub-layer 60 on the black matrix layer 20 and the color filter 30, and the metallic conductive sub-layer 70 on a side of the transparent conductive sub-layer 60 distal to the black matrix layer 20 and the color filter 30, the metallic conductive sub-layer 70 is not directly formed on the organic layers (the black matrix layer 20 and the color filter 30) of the display substrate. Because the transparent conductive sub-layer 60 has a relatively high adhesion both with the black matrix layer 20 and the color filter 30 on its first side, and with the metallic conductive sub-layer 70 on its second side, the metal fall-off issue can be obviated.

FIG. 3 is a schematic diagram illustrating the structure of an organic light emitting diode display substrate in some embodiments according to the present disclosure. Referring to FIG. 3, the organic light emitting diode display substrate in some embodiments does not have a continuous transparent conductive sub-layer 60 that extends substantially throughout the entire counter substrate as shown in FIG. 1 or FIG. 2. Instead, the transparent conductive sub-layer 60 is substantially limited to the inter-subpixel region 2. By having the transparent conductive sub-layer 60 substantially limited to the inter-subpixel region 2, light transmission in the display apparatus having the present display substrate can be further improved. At the same time, the transparent conductive sub-layer 60 is maintained between the metallic conductive sub-layer 70 and a layer made of an organic material, the metallic conductive sub-layer 70 can be securely adhered on the display substrate, obviating the metal fall-off issue in the conventional display substrate.

FIG. 4 is a schematic diagram illustrating the structure of an organic light emitting diode display substrate in some embodiments according to the present disclosure. Referring to FIG. 4, the organic light emitting diode display substrate in some embodiments includes an overcoat layer 40 on a side of the auxiliary cathode 50 distal to the base substrate 10, to further prevent the metal fall-off. In this configuration, the auxiliary cathode may be electrically connected to a cathode in an army substrate through the transparent conductive sub-layer 60 from a side of the display substrate.

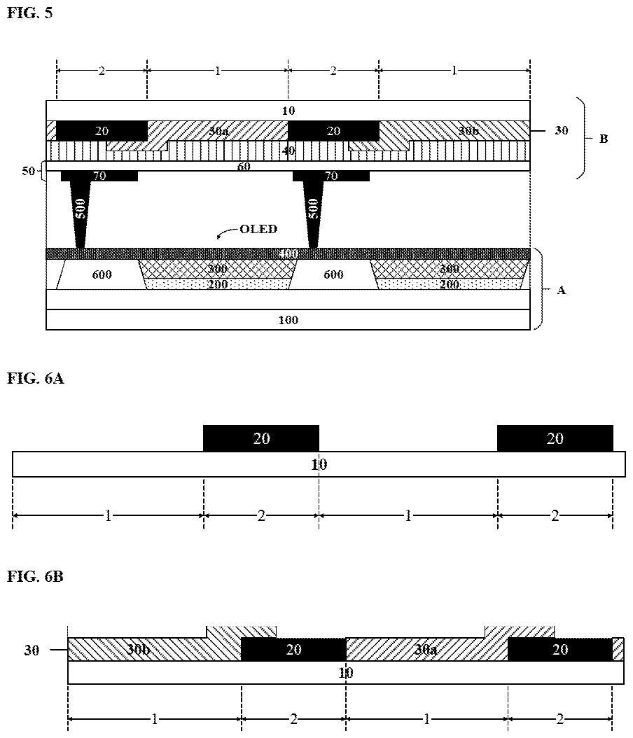

In another aspect, the present disclosure provides an organic light emitting diode display apparatus having the organic light emitting diode display substrate described herein or fabricated by a method described herein. In some embodiments, the organic light emitting diode display apparatus further includes an array substrate having a plurality of organic light emitting diodes. FIG. 5 is a schematic diagram illustrating the structure of an organic light emitting diode display apparatus in some embodiments according to the present disclosure. Referring to FIG. 5, the organic light emitting diode display apparatus has a subpixel region 1 and an inter-subpixel region 2. The organic light emitting diode display apparatus includes an array substrate A and a counter substrate B facing the array substrate A. The counter substrate in FIG. 5 is substantially the same as the organic light emitting diode display substrate depicted in FIG. 1. The array substrate A in some embodiments includes a plurality of organic light emitting diodes OLED. The plurality of organic light emitting diodes OLED are substantially in the subpixel region 1. Each of the plurality of organic light emitting diodes OLED includes an anode 200, an organic light emitting layer 300, and a cathode 400. In the present organic light emitting diode display apparatus, the cathode 400 in the array substrate A is electrically connected to the auxiliary cathode 50 in the counter substrate B. Optionally, the array substrate A further includes a pixel definition layer 600, which is substantially in the inter-subpixel region 2. Optionally, the organic light emitting diode display apparatus is a top emission type organic light emitting diode display apparatus.

The cathode 400 in the array substrate A may be electrically connected to the auxiliary cathode 50 in the counter substrate B by various appropriate methods. Referring to FIG. 5, the organic light emitting diode display apparatus in some embodiments further includes a plurality of post spacers 500 between the array substrate A and the counter substrate B, and spacing apart the array substrate A and the counter substrate B. One or more of the plurality of post spacers 500 may have a conductive material coating on the surface, thereby electrically connecting the cathode 400 and the auxiliary cathode 50.

Optionally, the cathode 400 and the auxiliary cathode 50 may be electrically connected to each other by other methods. In one example, the organic light emitting diode display apparatus includes a sealant layer between the array substrate A and the counter substrate B, and sealing the array substrate A and the counter substrate B into a cell. Optionally, the sealant layer includes a plurality of conductive beads. The sealant layer is electrically connected to (e.g., in contact with or by a connection line) both the cathode 400 and the auxiliary cathode 50, thereby electrically connecting the cathode 400 and the auxiliary cathode 50. Various alternative implementations may be practiced according to the present disclosure.

In another aspect, the present disclosure provides a method of fabricating an organic light emitting diode display substrate having a subpixel region and an inter-subpixel region. In some embodiments, the method includes forming an auxiliary cathode on a base substrate. The step of forming the auxiliary cathode according to the present method includes forming a transparent conductive sub-layer and forming a metallic conductive sub-layer on a side of the transparent conductive sub-layer distal to the base substrate. The metallic conductive sub-layer is formed substantially in the inter-subpixel region. Optionally, the metallic conductive sub-layer is formed to be in contact with the transparent conductive sub-layer.

By first forming a transparent conductive sub-layer on the display substrate, followed by forming the metallic conductive sub-layer on the transparent conductive sub-layer, the properties and performance of the auxiliary cathode are significantly enhanced. The transparent conductive sub-layer has a relatively high adhesion with the organic material layers (e.g., the overcoat layer, the black matrix layer, or the color filter). At the same time, the metallic conductive sub-layer also has a relatively high adhesion with the transparent conductive sub-layer. By making the auxiliary cathode to have the metallic conductive sub-layer stacked on the transparent conductive sub-layer, the overall resistance of the auxiliary cathode is further reduced, and the issue of metal fall-off the display substrate is obviated.

Specifically, the step of forming the transparent conductive sub-layer in some embodiments includes depositing a transparent conductive material on the base substrate in a room temperature deposition process. As used herein, the term “room temperature deposition” generally refers to a deposition process performed in a cooler and not intentionally heated deposition environment. For example, the deposition process may be performed in a deposition chamber under ambient conditions, e.g., at a temperature of approximately 25 degrees. Optionally, the room temperature deposition process is a room temperature sputtering process performed at approximately (but not necessarily exactly) room temperature. In another example, the room temperature deposition involves a sputtering process performed without additional heating of the substrate or the chamber. By forming the transparent conductive sub-layer in a room temperature deposition process, the damages to the layer made of an organic material in the counter substrate can be minimized, and an excellent adhesion with the underlying layer can be achieved as compared to other deposition methods.

In some embodiments, the method further includes forming a black matrix layer on the base substrate. Optionally, the step of forming the auxiliary cathode includes forming the auxiliary cathode on a side of the black matrix layer distal to the base substrate. The metallic conductive sub-layer is formed so that a projection of the black matrix layer on the base substrate substantially covers a projection of the metallic conductive sub-layer on the base substrate.

Optionally, the transparent conductive sub-layer is formed in both the subpixel region and the inter-subpixel region. Optionally, the step of forming the transparent conductive sub-layer includes depositing a transparent conductive material layer on the counter substrate, e.g., without patterning.

In some embodiments, the method further includes forming an overcoat layer on the base substrate. Optionally, the step of forming the auxiliary cathode includes forming the auxiliary cathode on a side of the overcoat layer distal to the base substrate. Optionally, the metallic conductive sub-layer is formed to be in contact with the transparent conductive sub-layer; and the transparent conductive sub-layer is formed to be in contact with the overcoat layer.

Optionally, the transparent conductive sub-layer is made of a metal oxide.

In some embodiments, the method further includes forming a color filter. Optionally, the transparent conductive sub-layer is formed so that a projection of the transparent conductive sub-layer on the base substrate substantially covers a projection of the color filter on the base substrate.

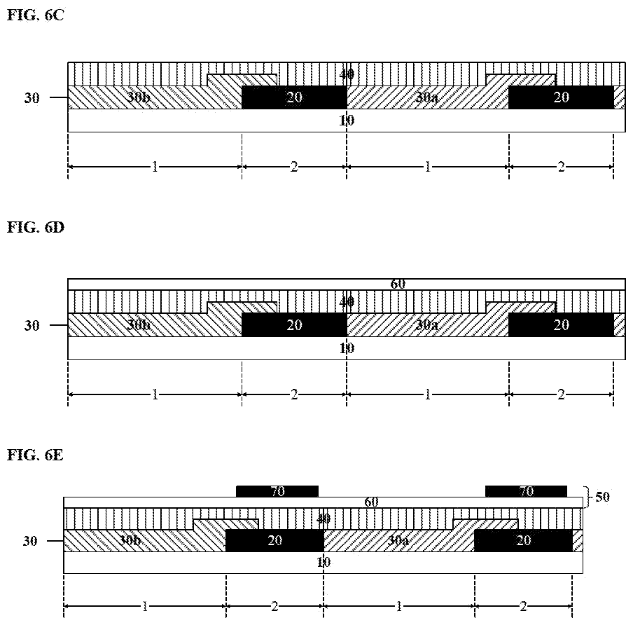

FIGS. 6A to 6E illustrate a process of fabricating an organic light emitting diode display substrate in some embodiments according to the present disclosure. Referring to FIG. 6A, a black matrix layer 20 is formed on a base substrate 10, the black matrix layer 20 is formed substantially in the inter-subpixel region 2. Referring to FIG. 6B, a color filter 30 is then formed on the base substrate 10. The color filter 30 is formed substantially in the subpixel region 1, and is formed to have a plurality of color filter blocks such as the color filter blocks 30a and 30b in FIG. 6B. Referring to FIG. 6C, subsequent to forming the black matrix layer 20 and the color filter 30, an overcoat layer 40 is formed on a side of the black matrix layer 20 and the color filter 30 distal to the base substrate 10, to planarize the surface of the display substrate. Referring to FIG. 6D, a transparent conductive sub-layer 60 is formed on a side of the overcoat layer 40 distal to the base substrate 10. The transparent conductive sub-layer 60 is formed using a room temperature sputtering process, and is formed to be in contact with the overcoat layer 40. An excellent adhesion between the transparent conductive sub-layer 60 and the overcoat layer 40 is achieved. The transparent conductive sub-layer 60 may be formed as a continuous layer extending throughout the subpixel region 1 and the inter-subpixel region 2. Referring to FIG. 6E, a metallic conductive sub-layer 70 is formed on a side of the transparent conductive sub-layer 60 distal to the base substrate 10. The metallic conductive sub-layer 70 is formed substantially in the inter-subpixel region. A projection of the black matrix layer 20 on the base substrate 10 substantially covers a projection of the metallic conductive sub-layer 70 on the base substrate 10.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”. “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An organic light emitting diode display substrate having a subpixel region and an inter-subpixel region, comprising:
a base substrate; and
an auxiliary cathode on the base substrate;
wherein the auxiliary cathode comprises a transparent conductive sub-layer and a metallic conductive sub-layer on a side of the transparent conductive sub-layer distal to the base substrate; and
the metallic conductive sub-layer is substantially in the inter-subpixel region.

2. The organic light emitting diode display substrate of claim 1, wherein the metallic conductive sub-layer is in contact with the transparent conductive sub-layer.

3. The organic light emitting diode display substrate of claim 1, further comprising a black matrix layer on the base substrate;
wherein the auxiliary cathode is on a side of the black matrix layer distal to the base substrate; and
a projection of the black matrix layer on the base substrate substantially covers a projection of the metallic conductive sub-layer on the base substrate.

4. The organic light emitting diode display substrate of claim 1, wherein the transparent conductive sub-layer is in the subpixel region and the inter-subpixel region.

5. The organic light emitting diode display substrate of claim 1, further comprising an overcoat layer on the base substrate;
wherein the auxiliary cathode is on a side of the overcoat layer distal to the base substrate.

6. The organic light emitting diode display substrate of claim 5, wherein the metallic conductive sub-layer is in contact with the transparent conductive sub-layer; and
the transparent conductive sub-layer is in contact with the overcoat layer.

7. The organic light emitting diode display substrate of claim 1, wherein the transparent conductive sub-layer comprises a metal oxide.

8. The organic light emitting diode display substrate of claim 1, wherein the organic light emitting diode display substrate is a color filter substrate comprising a color filter.

9. The organic light emitting diode display substrate of claim 8, wherein a projection of the transparent conductive sub-layer on the base substrate substantially covers a projection of the color filter on the base substrate.

10. An organic light emitting diode display apparatus, comprising an array substrate having a plurality of organic light emitting diodes; and the organic light emitting diode display substrate of claim 1 facing the array substrate;
wherein the array substrate comprises a cathode for the plurality of organic light emitting diodes; and
the cathode is electrically connected to the auxiliary cathode in the organic light emitting diode display substrate.

11. A method of fabricating an organic light emitting diode display substrate having a subpixel region and an inter-subpixel region, comprising:
forming an auxiliary cathode on a base substrate;
wherein forming the auxiliary cathode comprises forming a transparent conductive sub-layer and forming a metallic conductive sub-layer on a side of the transparent conductive sub-layer distal to the base substrate; and
the metallic conductive sub-layer is formed substantially in the inter-subpixel region.

12. The method of claim 11, wherein forming the transparent conductive sub-layer comprises depositing a transparent conductive material on the base substrate in a room temperature deposition process.

13. The method of claim 11, wherein the metallic conductive sub-layer is formed to be in contact with the transparent conductive sub-layer.

14. The method of claim 11, further comprising forming a black matrix layer on the base substrate;
wherein forming the auxiliary cathode comprises forming the auxiliary cathode on a side of the black matrix layer distal to the base substrate; and
the metallic conductive sub-layer is formed so that a projection of the black matrix layer on the base substrate substantially covers a projection of the metallic conductive sub-layer on the base substrate.

15. The method of claim 11, wherein the transparent conductive sub-layer is formed in the subpixel region and the inter-subpixel region.

16. The method of claim 11, further comprising forming an overcoat layer on the base substrate;
wherein forming the auxiliary cathode comprises forming the auxiliary cathode on a side of the overcoat layer distal to the base substrate.

17. The method of claim 16, wherein the metallic conductive sub-layer is formed to be in contact with the transparent conductive sub-layer; and
the transparent conductive sub-layer is formed to be in contact with the overcoat layer.

18. The method of claim 11, wherein the transparent conductive sub-layer is made of a metal oxide.

19. The method of claim 11, further comprising forming a color filter.

20. The method of claim 19, wherein the transparent conductive sub-layer is formed so that a projection of the transparent conductive sub-layer on the base substrate substantially covers a projection of the color filter on the base substrate.
